(19) United States
(12) Patent Application Publication
(10) Pub. No.: US 2026/0188373 A1
(43) Pub. Date: Jul. 2, 2026

(54) MEMORY AND METHOD FOR QUICK-READING MEMORY CELLS OF A MEMORY IN A DOUBLE DATA RATE CONFIGURATION

(71) Applicant: Ferroelectric Memory GmbH, Dresden (DE)

(72) Inventors: Menno Mennenga, Dresden (DE); Torsten Coym, Dresden (DE); Thomas Rückes, Dresden (DE)

(21) Appl. No.: 19/005,189

(22) Filed: Dec. 30, 2024

(51) Int. Cl. G11C 11/22; G06F 12/02

(52) U.S. Cl. CPC G11C 11/2273; G06F 12/0238; G11C 11/221

(57) ABSTRACT

Various aspects relate to a memory including: a bank including a first row and a second row, the first row including a first memory-array addressable by first wordlines and first bitlines connected to first sense-elements, the second row including a second memory-array addressable by second wordlines and second bitlines connected to second sense-elements; an I/O circuit configurable to carry out an I/O operation; a control circuit configured to: perform a read operation on the first memory-array to store a first word in the first sense-elements and the read operation on the second memory-array to store a second word in the second sense-elements; operate the I/O circuit to perform the I/O operation on one or more of the first or second sense-elements as a function of a first address associated with the I/O operation of the first row and a second address associated with the I/O operation of the second row.

### TECHNICAL FIELD

Various aspects relate to a memory and a method for quick-reading memory cells of a memory in a double data rate configuration.

### BACKGROUND

In general, various computer memory technologies have been developed in semiconductor industry. Various memory devices, such as solid-state discs (SSD), include a non-volatile storage (e.g., a flash storage) for persistently storing data and a volatile random-access memory, RAM (e.g., a dynamic random-access memory, DRAM, or a static random-access memory, SRAM) that provides a cache for volatilely storing data to thereby increase the random-access time for accessing these data. Thus, combining the usually slow accessible non-volatile (flash) storage with the fast accessible volatile random-access memory allows to mitigate the limitations of the non-volatile storage. However, the volatile random-access memory is expensive and the combination of both technologies is complex and, therefore, increases the cost further. As an alternative to the volatile random-access memory, a non-volatile memory (e.g., a resistive random-access memory (RRAM), magnetoresistive random-access memory (MRAM) a phase-change memory (PCM), etc.) may provide the cache.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows an exemplary memory device according to various aspects;

FIG. 2A to FIG. 2D schematically show an exemplary memory organization of a remanent-polarizable NVRAM according to various aspects;

FIG. 3 shows an exemplary memory cell arrangement including a plurality of memory cells and various control lines for addressing the plurality of memory cells;

FIG. 4 shows an equivalent circuit of a memory cell that, during a read-out operation, is provided with a read voltage to develop a characteristic voltage at the bitline;

FIG. 5 shows an example of a typical hysteresis curve of a remanent-polarizable memory structure that plots the polarization as a function of the voltage across it;

FIG. 6 shows a typical timing diagram of a read-out operation for determining a memory state of the memory cell;

FIG. 7 shows an exemplary configuration of a sense amplifier according to various aspects;

FIG. 8 shows a schematic configuration of a remanent-polarizable NVRAM according to various aspects;

FIG. 9 schematically shows a design of an x4 DDR4 configuration and FIG. 10 shows a timing diagram of reading a memory cell of thereof.

FIG. 11 shows a bank of the remanent-polarizable NVRAM with two open pages according to various aspects;

FIG. 12 shows a timing diagram of reading a memory cell of the remanent-polarizable NVRAM according to various aspects;

FIG. 13 shows an addressing of subarrays within a same memory bank according to various aspects;

FIG. 14 shows a flow diagram of a method for quick-reading memory cells of a memory in a double data rate configuration according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a memory cell, or a memory capacitor). However, it may be understood that aspects described in connection with methods may similarly apply to the devices, and vice versa.

Conventionally, a non-volatile (e.g., flash) memory of a memory device, such as solid-state discs (SSD), is coupled to a volatile random-access memory that provides a cache for volatile storage of data to faster access these data. However, the combination of both technologies is complex and, therefore, expensive.

Various aspects relate to a memory device that includes a remanent-polarizable non-volatile random-access memory (NVRAM), such as a ferroelectric NVRAM (Fe-NVRAM or FeRAM). The remanent-polarizable NVRAM allows to provide both, fast random-access similar to DRAM and persistent data storage.

According to various aspects, the NVRAM is capable to concurrently have at least two open pages per memory bank. Illustratively, the NVRAM is capable to cache a plurality of pages of a same bank, thereby significantly increasing the access time for accessing the stored memory states.

Various aspects relate to a memory including: a memory bank including a first memory row and a second memory row, wherein the first memory row includes a first memory array addressable by a first set of wordlines and a first set of bitlines, the first set of bitlines connected to a corresponding first set of sense elements, wherein the second memory row includes a second memory array addressable by a second set of wordlines and a second set of second bitlines, the second set of bitlines connected to a corresponding second set of sense elements; an input-output circuit configurable to, in an I/O operation, selectively input to or output from the first set of sense elements and the second set of sense elements; and a control circuit configured to: perform a read operation on the first memory array to store a first word associated with the first set of wordlines in the corresponding first set of sense elements; perform the read operation on the second memory array to store a second word associated with the second set of wordlines in the corresponding second set of sense elements; and operate the I/O circuit to perform the I/O operation on one or more operated sense elements of the first set of sense elements or of the second set of sense elements as a function of a first address associated with the I/O operation of the first memory row and a second address associated with the I/O operation of the second memory row.

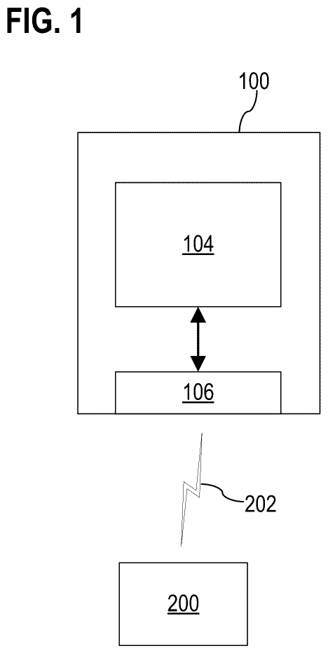

FIG. 1 shows an exemplary memory device 100 according to various aspects.

The memory device 100 may include remanent-polarizable non-volatile random-access memory (NVRAM) 104. The term remanent-polarizable NVRAM may refer to an NVRAM that includes a plurality of remanent-polarizable memory cells as detailed herein. The remanent-polarizable memory cells may be, for example, ferroelectric memory cells. In this case, the remanent-polarizable NVRAM 104 may also be referred to as ferroelectric NVRAM (Fe-NVRAM or FeRAM).

The memory device 106 may include a memory interface 106. The memory interface 106 may be configured to receive data from a host (CPU) 200 (e.g., a user device) via a communication channel 202 (e.g., to write the data to the remanent-polarizable NVRAM 104). The memory interface 106 may be configured to transmit data to the host 200 via the communication channel 202 (e.g., to provide data that are read from the remanent-polarizable NVRAM 104 responsive to the host 200 requesting them).

According to various aspects, the memory interface 106 may be a double data rate (DDR) type of interface. In the following, the memory device 100 is described as having a DDR type memory interface 106. It is understood that this serves for illustration and that the aspects detailed herein may apply accordingly to memory (or storage) devices having a different type of interface.

In the case of the DDR type memory interface 106, a memory controller for controlling the memory device 100 may be part of the host 200 (e.g., integrated in the host 200 CPU (and not part of the memory device 100). The memory device 100 may include a control circuit for carrying out read-and/or write operations of the remanent-polarizable NVRAM 104. The control circuit may also be referred to as control logic.

The memory device 100 may be configured in accordance with a double data rate (DDR) memory standard, such as DDR4 (see, for example, JEDEC standard JESD79-4D) or DDR5 (see, for example, JEDEC standard JESD79-5C.01), or any future standard. The control circuit may be or may include a command processor configured to carry out atomic operations. Thus, the control circuit may be, for example, configured to control read and/or write operations on the memory device 100. Herein, when referring to an action being carried out by at least one of the elements of the memory device 100, the memory circuit may be configured to control the at least one element accordingly.

Various configurational aspects of the memory device 100 including the remanent-polarizable NVRAM 104 are similar to that of a DRAM. Therefore, various aspects are detailed herein with reference to the DRAM configuration and, for the sake of conciseness, differences to the DRAM configuration are described.

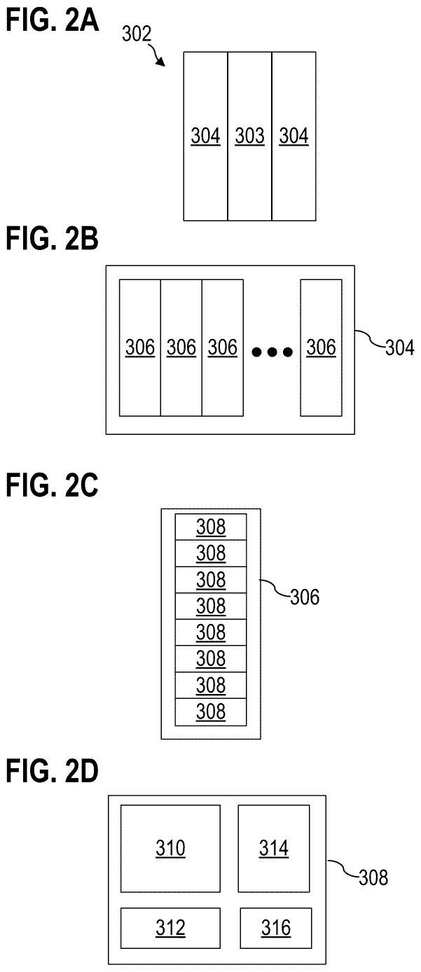

FIG. 2A to FIG. 2D schematically shows an exemplary memory organization of the remanent-polarizable NVRAM 104 in accordance with DDR4 and DDR5.

The remanent-polarizable NVRAM 104 may include one or more chips. Each chip of the one or more chips may include a plurality of memory cells logically divided into a plurality of bank groups. Each bank group of the plurality of bank groups may include a plurality of banks. FIG. 2A shows a bank 302 of the plurality of banks. Each bank 302 of the plurality of banks may include two half banks 304 coupled to a common secondary sense element (e.g., a secondary sense amplifier (short: sense amp)) 303. Each bank 302 may be configured to store 256 Mbit of data. With reference to FIG. 2B, each half bank 304 may include a plurality of (e.g., 32) segments 306. Each segment may be configured to store 4 Mbit of data. With reference to FIG. 2C, each segment 306 may include a plurality of (e.g., 8) subarrays 308. Each (memory) subarray 308 may be configured to store 512 kbit. With reference to FIG. 2D, each subarray 308 of the plurality of subarrays may include a (memory) array 310 for storing the (e.g., 512 kbit of) data, a row decoder 312 for addressing a row of the array 310, a plurality of primary sense elements (e.g., primary sense amplifiers) 314, and a magic square 316.

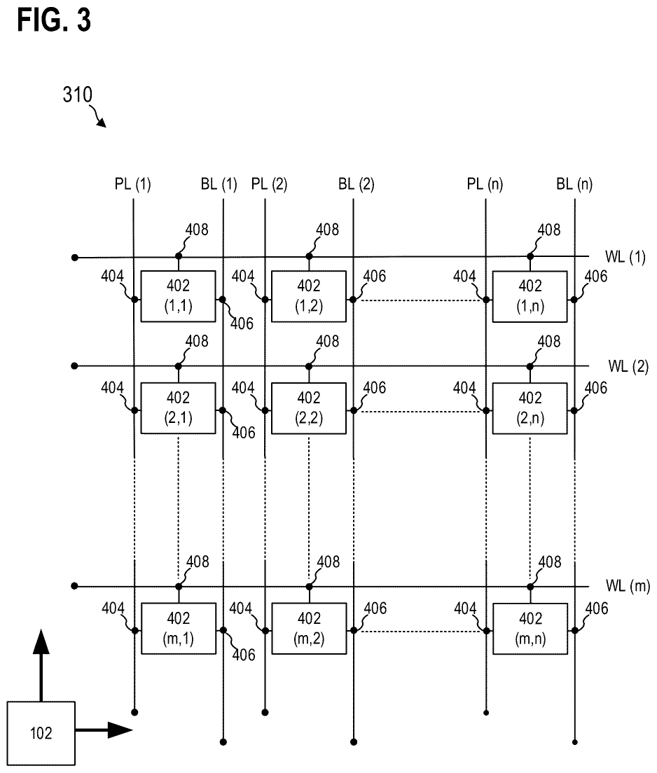

Each array 310 may be associated with a memory cell arrangement. FIG. 3 shows an exemplary memory cell arrangement including a plurality of memory cells 402(m=1 to M, n=1 to N). In the following, various aspects are detailed with reference to the memory cell arrangement 400. It is understood that the memory cell arrangement 100 serves as an exemplary memory cell arrangement to illustrate those aspects and that the memory cell arrangement may have any other suitable configuration.

The plurality of memory cells 402(m=1 to M, n=1 to N) may be arranged an array of N times M. “N” may be any integer number equal to or greater than one. “M” may be any integer number equal to or greater than one.

The memory cell arrangement 100 may include a plurality of bitlines BL(n=1 to N) (e.g., a plurality of even bitlines and a plurality of odd bitlines), a plurality of platelines PL(n=1 to N), and a plurality of wordlines WL(m=1 to M) for (individually and selectively) addressing the plurality of memory cells 402(m=1 to M, n=1 to N). Each memory cell 402(m*, n*) may be connected to and selectively (and individually) addressable via a corresponding bitline BL(n*) of the plurality of bitlines BL(n=1 to N), a corresponding wordline WL(m*) of the plurality of wordlines WL(m=1 to M), and a corresponding plateline PL(n*) of the plurality of platelines PL(n=1 to N). The *-notation may define one specific integer for the corresponding variable, such as a specific n* for the variable n, a specific m* for the variable m, etc. In some aspects, a subarray described herein may include only one plateline.

In this exemplary configuration, each memory cell 402(m*, n*) may be a three-terminal memory cell having a first terminal 404, a second terminal 406, and a third terminal 408. The first terminal 404 of a respective memory cell 402(m*, n*) may be coupled to the corresponding plateline PL(n*). The second terminal 406 of the respective memory cell 402(m*, n*) may be coupled to the corresponding bitline BL(n*). The third terminal 408 of the respective memory cell 402(m*, n*) may be coupled to the corresponding wordline WL(m*).

The control circuit may be configured to apply a respective voltage to each control line described herein. The control circuit (which may also be referred to as control logic) may be configured to apply a plateline voltage, V_{PL}, (via the corresponding plateline PL(n*)) at the first terminal 404, a bitline voltage, V_{BL}, (via the corresponding bitline BL(n*)) at the second terminal 406, and a wordline voltage, V_{WL}, (via the corresponding wordline WL(m*)) at the third terminal 408 of the memory cell 402(m*, n*) in order to address the memory cell 402(m*, n*). The control circuit (e.g., including and/or controlling a write circuit) may be configured to initiate (e.g., carry out) a write operation to write a memory state of at least one memory cell 402(m*, n*). The control circuit (e.g., including and/or controlling a read-out circuit) may be configured to initiate (e.g., carry out) a read-out operation to read out the memory state of the at least one memory cell 402(m*, n*).

“Writing” a memory cell, as used herein, may be understood as bringing the memory cell into one of at least two different memory states. Writing a memory cell may also be referred to as programming the memory cell, wherein the memory state the memory cell is residing in after programming may be called “programmed state”. Therefore, the memory cell may also be referred to as state-programmable memory cell.

“Reading” a memory cell, as used herein, may be understood as determining the memory state the memory cell is residing in (e.g., programmed to). In general, a memory cell may be read either non-destructively (if the read-out operation does not change the memory state the memory cell is residing in) or destructively (if the read-out operation changes the memory state the memory cell is residing in). The memory cells 402 described herein as an exemplary implementation may be read destructively. Thus, a destructive read-out operation may require a write operation subsequent to read-out in order to program again the memory state of the memory cell. It is understood that this subsequent write operation for writing back the read memory states may happen intrinsically without the user being required to transfer the data again.

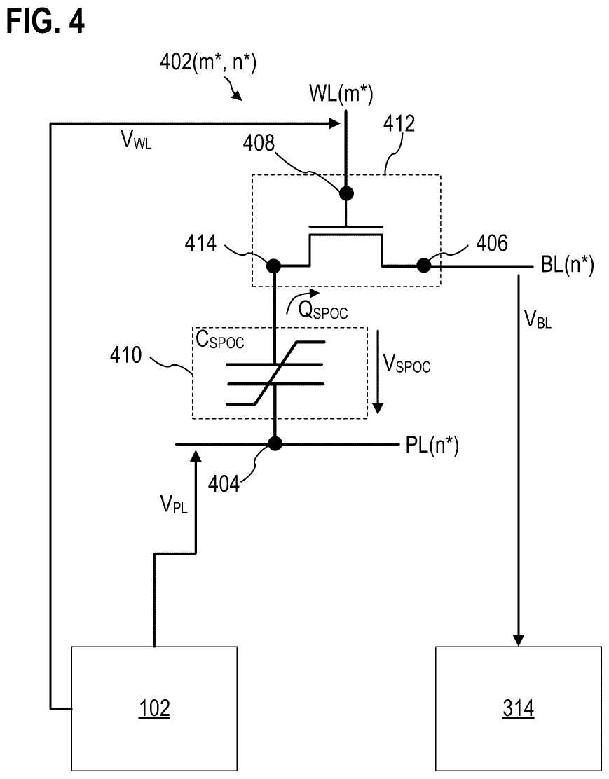

FIG. 4 shows an equivalent circuit of the memory cell 402(m*, n*) according to various aspects. As detailed herein, the memory cell arrangement serves as an exemplary memory cell arrangement; thus, the memory cell 402(m*, n*) described herein may also be part of any other memory cell arrangement configured differently.

The memory cell 402(m*, n*) may include the first terminal 404 coupled to the corresponding plateline PL(n*), the second terminal 406 coupled to the corresponding bitline BL(n*), and the third terminal 408 coupled to the corresponding wordline WL(m*).

The memory cell 402(m*, n*) may include a capacitive memory structure, such as a spontaneously polarizable capacitor, SPOC, structure 410. Therefore, the memory cell 402(m*, n*) may be referred to as capacitive memory cell or capacitor-type memory cell. The SPOC structure 410 may include a memory element disposed between at least two electrodes (e.g., two electrode layers).

The memory cell 402(m*, n*) may include an access device. Herein, for illustration, the access device is described exemplarily as a field effect transistor (FET), such as a field-effect transistor (FET) structure 412 providing the (e.g., n-type or p-type) FET. It is understood that this serves for illustration and that the access device may be any other kind of access device.

The field-effect transistor, FET, structure 412 may include a gate structure, wherein the gate structure may include a gate isolation and a gate electrode. The gate structure may be a planar gate stack or may have another field-effect transistor designs with a non-planar shape, for example a trench gate transistor design, a vertical field-effect transistor design, or other designs, such as a fin-FET design. The gate electrode may be connected to the third terminal 408. Therefore, the third terminal 408 may also be referred to as gate terminal. The FET structure 412 may include a first source/drain terminal and a second source/drain terminal. The second source/drain terminal may be connected to the second terminal 406 of the memory cell 402(m*, n*). A first electrode of the SPOC structure 410 may be coupled to the first terminal 404 and a second electrode of the SPOC structure 410 may be connected to the first source/drain terminal of the FET structure 412. The node coupled between the FET structure 412 and the SPOC structure 410 may be referred to as storage node (SN) 414 or storage terminal.

As detailed herein, the exemplarily described memory cell 402(m*, n*) may include at least one capacitor (the SPOC structure 410) and a transistor (the FET structure 412) such that the memory cell 402(m*, n*) may be a one transistor, T, one capacitor, C, memory cell (1T1C cell). It is understood that this serves for illustration and that the memory cell 402(m*, n*) may include more than one capacitor, thus being a one transistor multiple capacitors memory cell (1TxC cell).

The memory state of the memory cell may be associated with a polarization state of the SPOC structure 410 (e.g., its memory element). The polarization state of the SPOC 410 may determine the amount of charge stored therein. The amount of charge stored in the SPOC structure 410 may be used to define the memory state of the memory cell. Thus, writing the memory cell may be associated with applying an electric field over the SPOC structure 410 to thereby set (e.g., change) the (e.g., remanent) polarization state of the SPOC structure 410.

The memory element may include or may consist of a spontaneously polarizable material. For example, the spontaneously polarizable material may be a remanent polarizable material, such as a ferroelectric material, or a non-remanent polarizable material, such as an anti-ferroelectric material. A memory element including or consisting of a spontaneously polarizable material may be understood such that the memory element has (e.g., within the framework of the SPOC structure 410) spontaneously polarizable properties. The SPOC structure 410 may provide a spontaneously polarizable capacitor (in some aspects also referred to as memory capacitor).

The spontaneously-polarizable memory element may show a hysteresis in the (voltage (drop) dependent) polarization. The spontaneously-polarizable memory element may show non-remanent spontaneous polarization (e.g., may show anti-ferroelectric properties), e.g., the spontaneously-polarizable memory element may have no or no substantial remanent polarization remaining in the case that no voltage drops over the spontaneously-polarizable memory element. In other aspects, the spontaneously-polarizable memory element may show remanent spontaneous polarization (e.g., may show ferroelectric properties), e.g., the spontaneously-polarizable memory element may have a remanent polarization or a substantial remanent polarization remaining in the case that no voltage drops over the spontaneously-polarizable memory element.

The terms “spontaneously polarized” or “spontaneous polarization” may be used herein, for example, with reference to the polarization capability of a material beyond dielectric polarization. A “spontaneously-polarizable” (or “spontaneous-polarizable”) material may be or may include a spontaneously-polarizable material that shows a remanence, e.g., a ferroelectric material, and/or a spontaneously-polarizable material that shows no remanence, e.g., an anti-ferroelectric material. The coercivity of the spontaneously-polarizable material may be a measure of the strength of the reverse polarizing electric field that may be required to remove a remanent polarization.

A spontaneous polarization (e.g., a remanent or non-remanent spontaneous polarization) may be evaluated via analyzing one or more hysteresis measurements (e.g., hysteresis curves), e.g., in a plot of polarization, P, versus electric field, E, in which the material is polarized into opposite directions. The polarization capability of a material (dielectric polarization, spontaneous polarization, and a remanence characteristics of the polarization) may be analyzed using capacity spectroscopy, e.g., via a static (C-V) and/or time-resolved measurement or by polarization-voltage (P-V) or positive-up-negative-down (PUND) measurements. Another method for determining a polarization capability of a state-programmable memory element may include transmission electron microscopy, e.g., an electric-field dependent transmission electron microscopy.

The memory state may be understood as referring to a remanent polarization state that is set by applying a particular voltage across the SPOC structure 410 that is sufficient to set a corresponding polarization state, where, once set, the remanent polarization state is retained by the SPOC structure 410 even when the voltage across the SPOC structure 410 has been removed (e.g., it is remanently-polarizable). Once such a capacitive structure has been state-programmed to a remanent state, it generally retains the programmed state until it is re-programmed by applying a voltage across it that is sufficient to program the element to a (e.g., new) remanent state. As detailed herein, in a usual capacitive memory cell, the amount of charge stored in the capacitor structure may be used to define a memory state (e.g., a first amount of charge stored in the capacitor structure may define a first memory state and a second amount of charge stored in the capacitor structure and different from the first amount of charge may define a second memory state). As used herein, a (memory) state of a memory cell is described as “remanent” where the SPOC structure 410 is capable of retaining its programmed state even when it is not connected to a power source. As also used throughout, the current remanent state to which the memory element has been set may be referred to as the “stored” state, the “written” state, or the “programmed” state.

According to various aspects, in various types of applications, e.g., in memory technology, a remanent polarization as low as 0 μC/cm² to 3 μC/cm² may be regarded as no substantial remanent polarization. Such low values of a remanent polarization may be present in a layer or material due to undesired effects, e.g., due to a not ideal layer formation. According to various aspects, in various types of applications, e.g., in memory technology, a remanent polarization greater than 3 μC/cm² may be regarded as substantial remanent polarization. Such a substantial remanent polarization may allow for storing information as a function of a polarization state of a spontaneously polarizable layer or a spontaneously polarizable material.

In general, a remanent polarization (also referred to as retentivity or remanence) may be present in a material layer in the case that the material layer may remain polarized upon reduction of an applied electric field (E) to zero, therefore, a certain value for the electrical polarization (P) of the material layer may be detected. Illustratively, a polarization remaining in a material when the electric field is reduced to zero may be referred to as remanent polarization. Therefore, the remanence of a material may be a measure of the residual polarization in the material in the case that an applied electric field is removed. In general, ferroelectricity and anti-ferroelectricity may be concepts to describe a spontaneous polarization of a material similar to ferromagnetism and anti-ferromagnetism used to describe remanent magnetization in magnetic materials. According to various aspects, an electric coercive field, E_{C}, (also referred to as coercive field) may be or may represent the electric field required to depolarize a remanent-polarizable layer. In some aspects, the memory element may be remanent-polarizable, thereby providing the remanent polarization capability of the SPOC structure 410. In other aspects, the memory element may consist of a material that is spontaneously polarizable but shows no remanence (e.g., an anti-ferroelectric material) and additional conditions are implemented to generate an internal electric-field within the anti-ferroelectric material to thereby provide the remanent polarization capability of the SPOC structure 410. Hence, a non-remanently polarizable material, such as an anti-ferroelectric (“antiferroelectric”) material may exhibit remanent polarizable properties within certain structures. An internal electric-field within an anti-ferroelectric material may be caused (e.g., applied, generated, maintained, as examples) by various strategies: e.g., by implementing floating nodes that may be charged to voltages different from zero volts, and/or by implementing charge storage layers, and/or by using doped layers, and/or by using electrode layers that adapt electronic work-functions to generate an internal electric field, by using an encapsulation structure which introduces compressive stress or tensile stress onto the memory element, thereby establishing the spontaneously polarizable properties, only as examples.

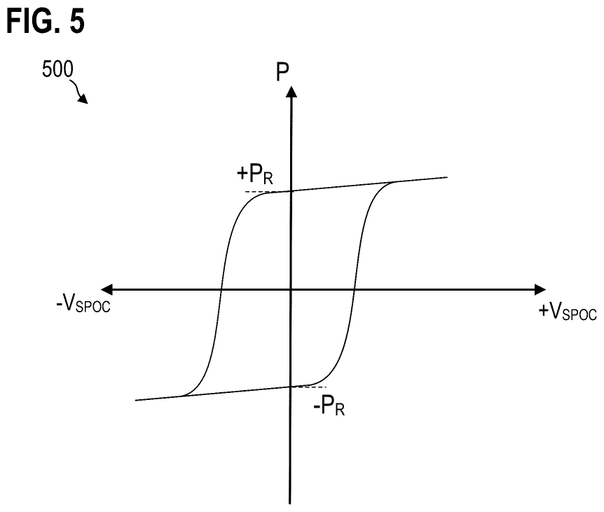

FIG. 5 shows a typical hysteresis curve 500 of a remanent-polarizable memory cell, where the polarization, P, is plotted as a function of the voltage, V_{SPOC}, across the SPOC structure 410. The voltage, V_{SPOC}, across the SPOC structure 410 may be a voltage difference between a voltage applied at the first terminal 404 (i.e., the plateline voltage V_{PL}) and a voltage applied at the storage node 414 and. FIG. 5 shows the (capacitive) memory cell 402(m*, n*) exemplarily as a remanent-polarizable memory cell to illustrate various aspects thereof. The graph shows two remanent polarization states (+P_{R}, −P_{R}) of the memory element that may represent the programmable states of the memory element. For example, the memory cell 402(m*, n*) may be programmed to remanent polarization state +P_{R} (representing, for example, a bit of digital information with a value of “0”) or to remanent polarization state −P_{R} (representing, for example, a bit of digital information with a value of “1”), or vice versa, by applying a programming voltage across the SPOC structure 410 that is sufficient to program the corresponding remanent polarization state (e.g., via applying a plateline voltage V_{PL} and a bitline voltage V_{BL}).

To read the stored memory state of the SPOC structure 410, a read voltage is typically applied across the SPOC structure 410 that is sufficient to program a remanent state of the state-programmable memory element to a predefined state. This develops a charge, Q_{SPOC}, that depends on the programmed state before the read voltage was applied, where if the read-out operation caused the state-programmable memory element to switch to a new state (e.g., the predefined state is different from the previously programmed state), a larger charge (resulting from a dielectric charge of the memory element and a switching charge (also referred to as polarization charge) due to switching the memory (polarization) state) will be provided, whereas if the read operation caused the state-programmable memory element to be re-programmed to the same state (e.g., the predefined state is the same as the previously programmed state), little charge (resulting from a dielectric charge of the memory element) will be provided from the memory element.

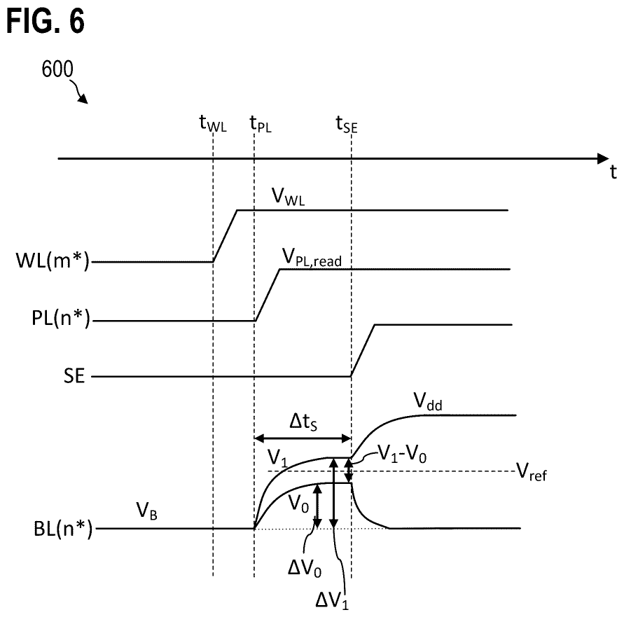

In the following, an exemplary read-out operation for reading the memory state of the memory cell 402(m*, n*) is detailed with reference to FIG. 4 and FIG. 6 which shows a typical timing diagram 600 of a read-out operation.

During a read-out operation, the corresponding bitline BL(n*) may be first discharged to the base voltage, V_{B}, (e.g., ground, GND). Then, a wordline voltage, V_{WL}, may be applied (at a wordline charging time step t_{WL}) to the corresponding wordline WL(m*) to activate (e.g., open) the access device (such as the FET structure 412). Once, a plateline voltage, V_{PL}, (e.g., a read plateline voltage, V_{PL, read}) is applied (at a plateline charging time step t_{PL}) to the corresponding plateline PL(n*), the charge (Q_{SPOC}) is provided to corresponding BL(n*) that depends on the (programmed) memory state of the SPOC structure 410 and its dielectric capacitance. Due to this, a characteristic voltage is developed onto the corresponding BL(n*). With reference to FIG. 6, a first voltage V₁ may develop onto the corresponding BL(n*) in the case that the memory cell 402(m*, n*) stores a logic “1” (also referred to as “1” bit) as memory state and a second voltage V₀ may develop onto the corresponding BL(n*) in the case that the memory cell 402(m*, n*) stores a logic “0” (also referred to as “0” bit) as memory state. The time until fully charging the corresponding BL(n*) may be referred to as signal development time, Δtₛ. The difference between the first voltage V₁ and the second voltage V₀ may define the read window (V₁−V₀).

It is understood that there may also be a charging of the corresponding bitline BL(n*) due to a capacitive ratio between a dielectric capacitance that is intrinsic to the memory cell and a capacitance of the node to which it is connected, such as the corresponding bitline BL(n*). As a result, the (bitline) voltage to which the corresponding bitline BL(n*) is charged to during a read-out operation (short: read operation) may depend not only on the switching charge but also on the capacitive ratio. This is why when the memory state is not switched during the read-out operation (e.g., the read state is the same as the predefined state, e.g., a logic “0”), a voltage is still provided. For example, if a memory cell is configured to provide a dielectric charge to the corresponding bitline BL(n*) by applying the plateline voltage, V_{PL}, when the memory element does not flip states (e.g., reading a “0” when the predefined state is also a logic “0”) and delivers little to no charge to the corresponding bitline BL(n*), the voltage on the bitline will be V_{PL}*C_{dielectric}/(C_{dielectric}+C_{BL}), where C_{dielectric} is the dielectric capacitance of the memory element and is the C_{BL} capacitance of the corresponding bitline BL(n*).

With reference to FIG. 4, the control circuit may be configured to apply, during the read-out operation, the plateline voltage, V_{PL}, and the wordline voltage, V_{WL}. The corresponding bitline BL(n*) may be connected to a corresponding sense element 314 of the plurality of sensing circuits of the subarray 308. According to various aspects, the memory cells that share a common bitline BL(n) may be connected to a same sense element 314. In the read-out operation, the sense element 314 may be configured to sense the voltage developed at the bitline (i.e., the bitline voltage V_{BL}) and compare the sensed voltage with a predefined reference voltage, V_{ref} (see, for example, FIG. 6). Thus, if the developed bitline voltage, V_{BL}, is greater than the predefined reference voltage, V_{ref}, (in the case of V₁) the memory state is determined as a “1” and if the developed bitline voltage, V_{BL}, is less than the predefined reference voltage, V_{ref}, (in the case of V₀) the memory state is determined as “0”. Therefore, the reference voltage, V_{ref}, may also be referred to as threshold voltage. The sense element 314 may, for example, be or include a sense amplifier. The sense amplifier may discharge the corresponding bitline BL(n*) to the base voltage, V_{B}, in the case that the memory state is a logic “0” and may charge the corresponding bitline BL(n*) to the (positive) supply voltage, V_{dd}, in the case that the memory state is a logic “1”. To write the memory cell 402(m*, n*) into a logic “1” (as memory state), the (positive) supply voltage, V_{dd}, may be applied at the corresponding bitline BL(n*) and about 0 V may be applied at the corresponding plateline PL(n*). To write the memory cell 402(m*, n*) into a logic “0” (as memory state), the (positive) supply voltage, V_{dd}, may be applied at the corresponding plateline PL(n*) and about 0 V may be applied at the corresponding bitline BL(n*).

As understood, a single sense element may be connected to multiple memory cells that are part of a same group and therefore share a common bitline BL(n*).

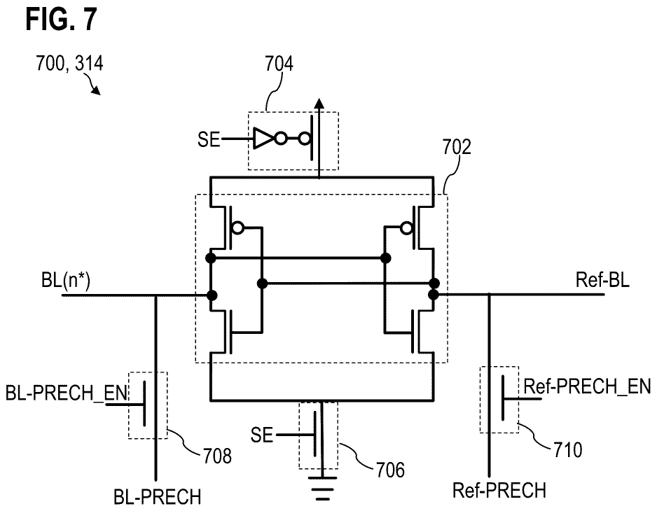

FIG. 7 shows an exemplary configuration of a sense amplifier 700 as an exemplary sense element 314 according to various aspects. The sense amplifier 700 may be differential or dual-sided, where one side of the sense amplifier 700 is connected to one bitline (such as the corresponding bitline BL(n*) of one array of memory cells and the other side of the sense amplifier 700 is connected to another bitline (such as a reference bitline, Ref-BL) of a different array of memory cells. In a dual-sided configuration, one side of the sense amplifier 700 may be actively operated to read a bitline (such as the corresponding bitline BL(n*) in the present example) of one set of cells while the other side (its complement) of the sense amplifier acts as a reference (such as the reference bitline, Ref-BL, in the present example), and vice versa. The corresponding bitline BL(n*) may be an even bitline and the reference bitline, Ref-BL, may be an odd bitline, or vice versa. In a dual-sided sense amplifier configuration, each sense amplifier may be understood as a latch 702 whose two inputs are the two bitlines, where the latch is enabled by a sense enable (SE) signal (e.g., provided at a sense enable time step t_{SE}) . The latch 702 may be connected via one or more sense enable transistors/switches 704, 706 that, when enabled, connects one side (the corresponding bitline BL(n*) in the present example) of its supply to a supply power and the other side (the reference bitline, Ref-BL, in the present example) of its supply to the base voltage (e.g., ground). The enable transistors/switches 704, 706 may be operated by the sense enable (SE) signal to supply power to the latch 702 when the SE signal is enabled and to leave the supply floating when the SE signal is not enabled. The side of the latch 702 may be selected by pre-charging transistors/switches 308, 310 which may be operated by corresponding (enable) signals (BL-PRECH_EN, Ref-PRECH_EN) that, when enabled, connect the corresponding bitline to its corresponding source voltage (BL-PRECH, REF-PRECH) for charging/discharging the corresponding bitline.

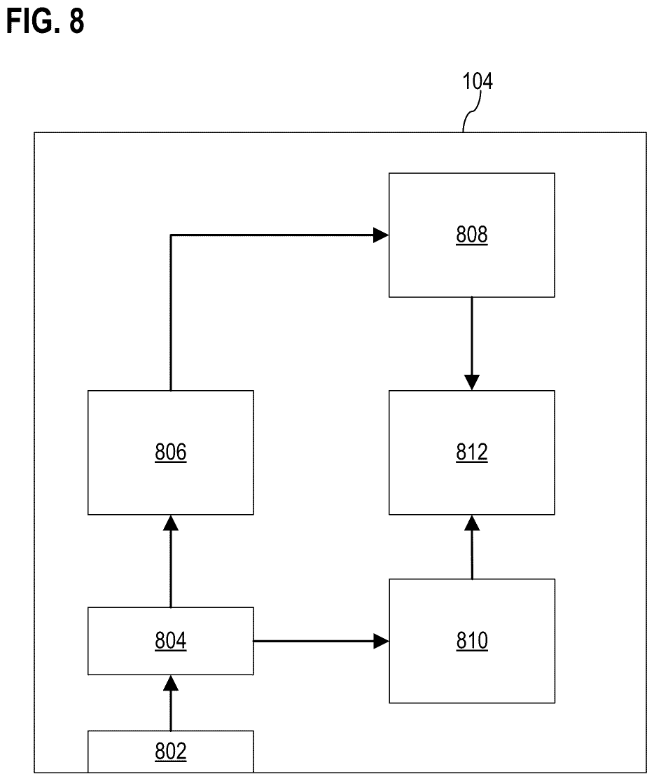

FIG. 8 shows a schematic configuration of the remanent-polarizable NVRAM 104 illustrating the general concept of reading the memory state of a memory cell 402(m*, n*). The remanent-polarizable NVRAM 104 may include an NVRAM interface 802 for communication with the control circuit. An address register 804 may receive the physical address of the memory cell 402(m*, n*) that is to be read according to a respective state of (e.g., voltage applied to) a plurality of address pins of the NVRAM interface 802. The remanent-polarizable NVRAM 104 may include a plurality of memory cells 808 organized as described with reference to FIG. 2.

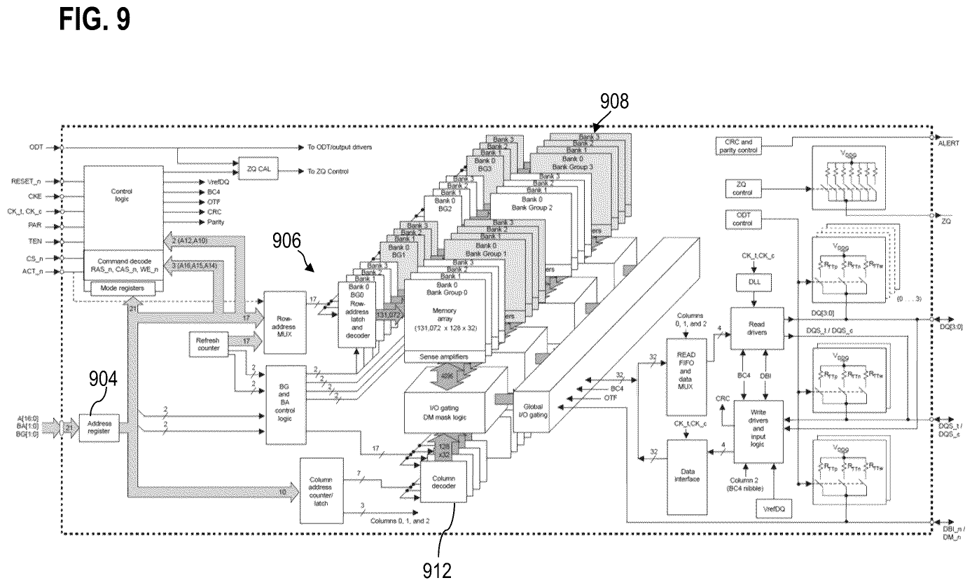

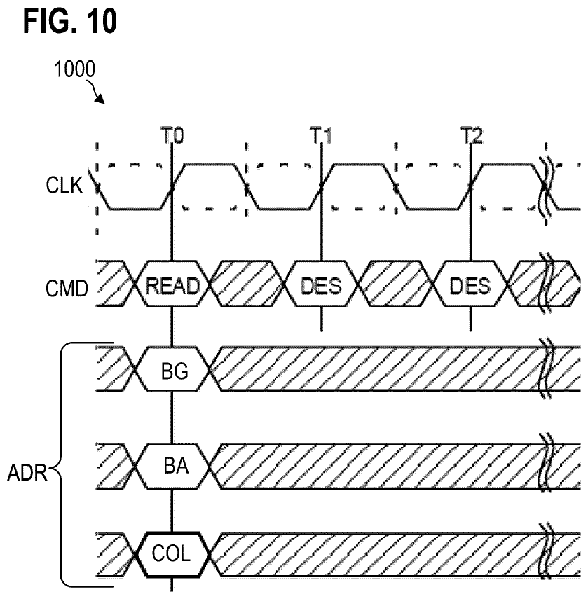

FIG. 9 schematically shows a design of an x4 DDR4 configuration. The x4 DDR4 configuration includes four bank groups (BG0 to BG3) with four banks (BA0 to BA3) each. The address register 904 receives the physical address of the memory cell 402(m*, n*) of the plurality of memory cells 908 that is to be read according to a respective state of a plurality of address pins A0 to Ax (depending on the density, with Ax being, for example, A14 in the case of a 512 Mb x4 configuration, A15 in the case of a 1 Gb x4 configuration, A16 in the case of a 2 Gb x4 configuration, A17 in the case of a 2 Gb x4 configuration), BA0, BA1, BG0, BG1 In detail, the bank group (BG) pins indicate in which bank group the memory cell 402(m*, n*) is in, the bank address (BA) pins indicate in which of the four banks the memory cell 402(m*, n*) is in, and the A address pins indicate in which row the memory cell 402(m*, n*) is in. A row of memory cells refers to memory cells connected to a same wordline, WL(m). Hence, the integer m may indicate the row.

To read the memory state (remanent state) of the memory cell 402(m*, n*), the wordline voltage, V_{WL}, is applied at the wordline, WL(m), indicated by the A address pins of the bank indicated by the BA pins within the bank group (BG) indicated by the BG pins (to open their FET structures 412); and the plateline voltage, V_{PL}, is applied to the platelines PL(1) to PL(n) of the array 310 the memory cell 402(m*, n*) is in. Thereby, each of the bitlines BL(1) to BL(n) of the array 310 is charged to its respective characteristic voltage and is sensed using the plurality of sense elements 314. This procedure may be carried out in response to an activate (ACT) signal. Illustratively, the respective memory state of all memory cells 402(m*, n=1 to N) is read (into the plurality of sense elements 314). The memory states of the memory cells 402(m*, n=1 to N) sensed by the plurality of sense elements 314 of the subarray 308 the memory cell 402(m*, n*) is in may be stored in a (local) row buffer. The memory states of the memory cells 402(m*, n=1 to N) may also be referred to as a word or a page.

The selection of the bank group, bank, and row is carried out using a row selection circuitry 906.

According to DDR standards, only one row (associated with WL(m*)) of one array 310 of one bank is read at a same time. Prior to reading another row of the same array or another array (e.g., of this bank), the read memory states of the memory cells 402(m*, n=1 to N) have to be written back. Thus, since there is only a single row read per bank, the memory state of the memory cell 402(m*, n*) can be read by a column decoder 912 using the bank group, BG, the bank address, BA, and the column n* (which is indicated by the A address pins). FIG. 10 shows a corresponding timing diagram 1000 illustrating the address space, ADR, of the DDR4 configuration including the bank group address, BG, the bank address, BA, and the column address, COL. The column decoder 912 may be configured to turn on switches between the corresponding bitline BL(n*) (pairs) and global bitline (pairs) and the voltage at the global bitline (pair) is sensed by the secondary sense element (e.g., secondary sense amplifier) 303.

It is understood that the x4 DDR4 configuration is described as an exemplary reference and that any other kind of DDR4 configuration may serve as reference (e.g., x8 DDR4, x16 DDR4, or any DDR5 configuration).

As detailed herein, in a DRAM-based DDR configuration, a page has to be closed prior to reading another page (viz. row) in the same bank by writing the read memory states of the memory cells 402(m*, n=1 to N) back. In a close-page policy, the read page may be closed immediately which allows to access a different page with lower latency. In an open-page policy, the page may be kept open (viz. stored in the row buffer) which allows to access the same page with lower latency, but the page has to be closed prior to reading a different page. Therefore, in DRAM-based DDR configuration, there are three signals associated with reading a memory cell 402(m*, n*) (viz. its memory state): The ACT signal for charging the wordline WL(m*) to charge the corresponding bitlines BL(n=1 to N) of the array 310 and to sense the characteristic voltages at the bitlines BL(n=1 to N) and to read the memory states into the row buffer, a READ signal to select the column n* of the memory cell 402(m*, n*) to be read and to read its memory state and/or a WRITE signal to write a memory state to be written into the row buffer, and a precharge (PRE) signal for closing the page (viz. for writing back the memory states of the memory cells 402(m*, n=1 to N)). Thus, in DRAM-based DDR configuration, there is always an ACT signal and a subsequent PRE signal prior to a new ACT signal for reading another row of the bank. Illustratively, the ACT signal and the PRE signal always occur pairwise.

It is understood that, when referring herein to reading/writing a memory cell(s), the read/write operation may not directly on the memory cell(s), but on the row buffer, viz. the sense elements (e.g., sense amps). Data may be written to the memory cell(s) as a secondary effect as a consequence of the state in the sense amp(s) being flipped during a write operation, for example.

Although, in DRAM-based DDR configuration, there may be open pages within different banks 302, these open pages have to be closed periodically (every 7.9 μs in the case of DDR4) since DRAM requires a refresh operation. Thus, in DRAM, open pages is unavailable regularly. The refresh operation includes re-writing the memory state of each memory cell since the DRAM memory cells lose their contents (viz. memory state) over time even if they are not accessed (which is why it is called “dynamic” RAM). The read-out operation differentiates from the refresh operation merely in that the refresh operation does not require the column selection since the primary sense elements 314 are enough for reading and re-writing the memory state.

In the following, various aspects of the remanent-polarizable NVRAM 104 are described in further detail with reference to the DDR configuration. It is understood that this serves for illustration and that the remanent-polarizable NVRAM 104 may be configured differently. Configuring the remanent-polarizable NVRAM 104 in accordance with a DDR standard (e.g., DDR4 or DDR5) may allow to implement the remanent-polarizable NVRAM 104 described herein into DDR devices, thereby allowing its applicability with reduced cost.

Due to the non-volatility of the SPOC structure 410, and, thus, the non-volatility of the remanent-polarizable NVRAM 104, the remanent-polarizable NVRAM 104 does not require the refresh operation of the DRAM. Hence, since each memory cell 402(m, n) stores its memory state persistent, periodic re-writing of the memory state is not required.

According to various aspects, the control circuit may be configured to open at least two pages within a same bank 302 concurrently (hence, at least partially overlapping in time). Hence, according to various aspects, there may be at point in time at which at least two pages within the same bank 302 are open. As detailed herein, an open page may refer to a (memory) row which is read to the (local) row buffer of the subarray 308 the (memory) row belongs to.

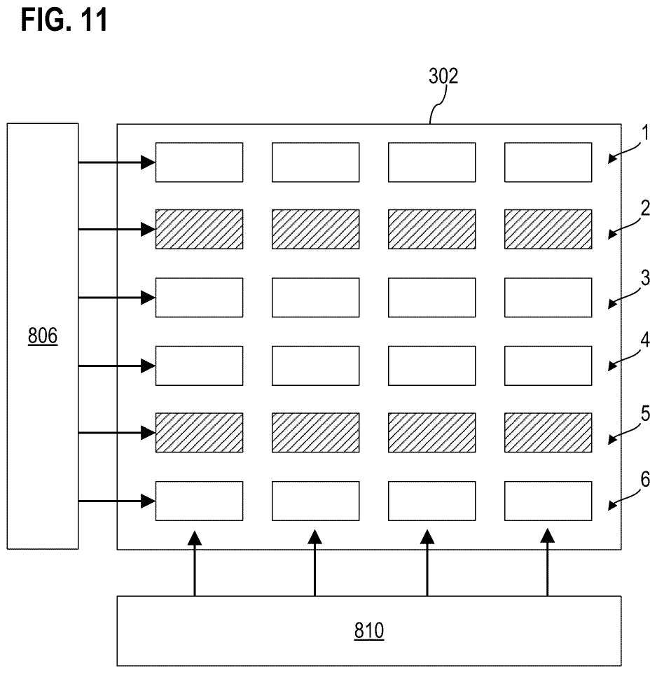

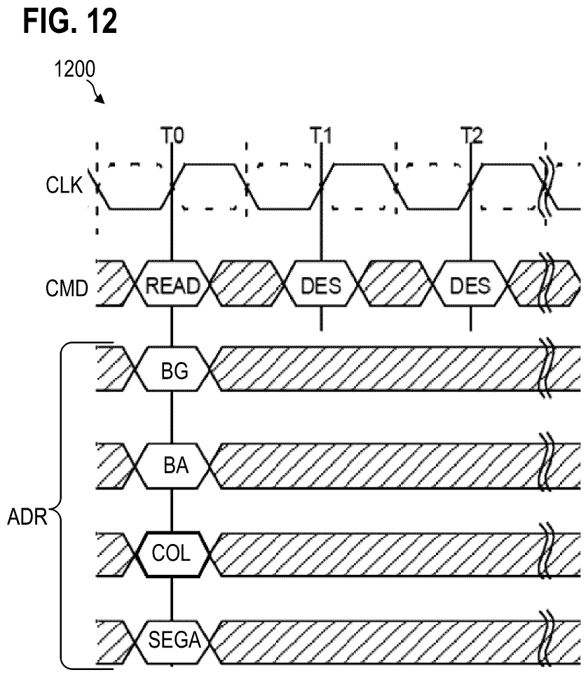

FIG. 11 shows a bank 302 of the remanent-polarizable NVRAM 104 with two open pages 2, 5 (indicated by the dashed rows, whereas closed pages are indicated by empty rows) according to various aspects. In the following, for illustration, it is referred in various aspects to two open pages (viz. two memory rows read to a respective local buffer). It is understood that this serves for illustration and that there may be more than two open pages at a same point in time.

As detailed herein, each subarray 308 may include a respective plurality of sense elements 314. Thus, there may be one local row buffer for each subarray 308. Thus, it is understood that the at least two open pages described herein may refer to at least two corresponding memory rows of different (memory) subarrays 308.

Thus, in general, the control circuit may be configured to control the remanent-polarizable NVRAM 104 to have up to P open pages at a same time with P being the number of segments per bank 302 (e.g., P=32 when having 32 segments per half bank).

The control circuit may be configured to initiate the read-out operation (in some aspects referred to as read operation) of a first memory row 2 of the (memory) bank to store a first word in the local row buffer of a (first subarray in a) first segment the first memory row 2 belongs to (viz to open the page associated with the first memory row 2). This read-out-operation may include providing the ACT signal for activating and sensing the memory states of the memory cells of the first memory row 2. Prior to providing the PRE signal for writing the memory states back to the memory cells of the first memory row 2, the control circuit may initiate the read-out operation of a second memory row 5 of the (memory) bank to store a second word in the local row buffer of a (second subarray in a) second segment the second memory row 5 belongs to (viz to open the page associated with the second memory row 5). This read-out-operation may include providing the ACT signal for activating and sensing the memory states of the memory cells of the second memory row 5. Writing the memory states back responsive to the PRE signal may also be referred to as closing a page.

An open page can be accessed at least two times faster as compared to first reading the memory states of the memory cells of a memory row into the row buffer. Thus, the more pages of a same bank 302 can be open at the same time, the faster the memory access of the memory device 100. Since the remanent-polarizable NVRAM 104 does not require the refresh operation, the open pages can also stay open for a much longer time period (theoretically, indefinitely) as compared to DRAM pages. For example, according to various aspects, the at least two open pages may stay open over a duration of more than 14 μs (microseconds). Illustratively, the open pages of the remanent-polarizable NVRAM 104 may provide (e.g., serve as) memory cache. Since the remanent-polarizable NVRAM 104 already includes the row buffer for reading and writing the memory cells, the memory cache can be provided without any additional cost.

The control circuit may include an activation circuit configured to provide the ACT signals for opening the at least two pages. For example, the activation circuit may be configured to provide a first ACT signal to bring the first memory row 2 into an activated state to thereby store the first word in the plurality of sense elements 314 associated with the first memory row, and may be configured to provide a second ACT signal to bring the second memory row 5 into an activated state to thereby store the second word in the plurality of sense elements 314 associated with the second memory row. As detailed herein, the first memory row 2 and the second memory row 5 may be in the activated state concurrently. Hence, according to various aspects, a bank 302 may be receive at least two ACT signals from the control circuit without a PRE signal in between.

As detailed herein, the control circuit may be configured to provide a READ signal for selecting the column n* of the memory cell 402(m*, n*) to be read and/or a WRITE signal to write a memory state to be written into the row buffer. This transfer of information may be carried out by an input-output (I/O) circuit 812. The I/O circuit 812 may be configured to,, in an I/O operation, selectively input to (e.g., in response to a WRITE signal) or output from (e.g., in response to a READ signal) the row buffer of a corresponding subarray (e.g., via the row buffer to the plurality of sense elements of the subarray). According to various aspects, the plurality of sense elements 314 may also be referred to as set of sense elements. The (local) row buffer may also be referred to as sense element buffer and/or sense amp buffer.

Hence, in order to carry out this I/O operation in the scenario of at least two open pages, the address space, ADR, further includes (in addition to the bank group address BG, the bank address BA, the column address, COL) an additional address that indicates the subarray (or segment as detailed below) of the memory row that is to be read. Illustratively, as shown in FIG. 11, there is an overlap of the row address space and the column address space within the same bank when having at least two open pages at the same time. Hence, the I/O circuit 812 may be configured to carry out the I/O operation as a function of an address, ADR, associated with (e.g., indicating) the memory row to be read. Thus, there may be a first address indicating the first memory row 2 and a second address indicating the second memory row 5 within the same memory bank 302. The I/O operation may include selecting the column n* and to input to or output from the sense element associated with the column n*.

In the following, various exemplary implementations are detailed that allow to address the at least two open pages compatible with DDR4 and DDR5. It is understood that this serves as an example and that, in some aspects, the NVRAM interface 802 may include additional pins not yet specified by any DDR standard (viz. having any kind of DDR type memory interface 106) which allow to address the at least two open pages. For example, there may be additional address pins that allow to address each subarray 308 of a same bank individually, thereby increasing the number of pages that can be open at the same time significantly.

In x4 and x8 DDR (having 3D configuration), the interface includes the A address pins (A0 to Ax) of which (according to the current standards) some of the A pins (e.g., the A11, A13, and A17 pins as an illustrative example) are not used for accessing the column (see, for example, FIG. 9 and FIG. 10 and corresponding description). According to various aspects, these pins (such as A11, A13, and A17) may be used as address pins indicating the open page that is to be read. Hence, using, for example, the pins A11, A13, and A17 (as 3 selection bits) allows to address 8 open pages per bank.

DDR standards further specify the pins C0, C1, and C2 which are used to address different chips in multi-die package (3DS) configurations (e.g., chip ID). Thus, in the case that there is only one chip, these pins C0, C1, and C2 may be used as address pins indicating the open page that is to be read. Hence, using the pins C0, C1, and C2 (as 3 selection bits) allows to address 8 open pages per bank.

According to various aspects, in an x4 or x8 DDR configuration, the pins A11, A13, and A17 and the pins C0, C1, and C2 may be used as address pins indicating the open page that is to be read. Using these pins (as 6 selection pins) allows to address 64 (8 times 8) open pages per bank.

As detailed herein, each bank 302 may include two half banks 304 and each half bank 304 may include 32 segments 306. Thus, each bank 302 may include 64 segments. Thus, when using the pins A11, A13, A17, C0, C1, and C2 each of the 64 segments can be addressed. FIG. 12 shows a timing diagram 1200 of reading a memory cell of the remanent-polarizable NVRAM 104, wherein the address ADR includes a segment address SEGA indicating the segment in which the memory row that is to be read is in. Hence, in this exemplary case, there may be one open page per segment 306. Thus, in comparison to DRAM which allows only one open page per bank, the number of open pages per bank 302 can be increased to 64. In the case of x4 and x8 having 4 bank groups with 4 banks each, the number of fast accessible memory is 4*4*64*1KByte=1MByte. Illustratively, in comparison to the row selection circuitry 906, the row selection circuitry 806 of the remanent-polarizable NVRAM 104 may be configured to also select an individual segment (and in some aspects even an individual subarray).

According to various aspects, the segments within a bank may be grouped into segment groups. In this case, the C0, C1, and C2 pins may be used to select the segment group and the A11, A13, A17 pins may be used to select the segment within the segment group, or vice versa.

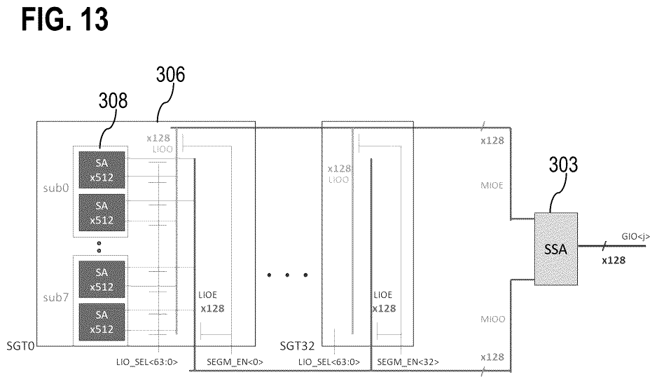

Inputting to or outputting from a (local) row buffer requires to connect the secondary sense element (e.g., secondary sense amp) 303 to this (local) row buffer. Therefore, the remanent-polarizable NVRAM 104 may include switches that allow the secondary sense element 303 to switch between different (local) row buffers. FIG. 13 shows an exemplary addressing of subarrays 308 within a same memory bank 302 according to various aspects. Each segment 306 may include local I/O data lines, LIO (e.g., even local I/O data lines LIOE and odd local I/O data lines LIOO) connected to the row buffer of the plurality of sense elements 314 of the segment 306. According to various aspects, the remanent-polarizable NVRAM 104 may include a plurality of (control) switches configured to connect a respective local I/O data line LIO of the local I/O data lines of the segment 306 to the secondary sense element 303 as a function of the address ADR (including the segment address SEGA indicating the segment 306). For example, the remanent-polarizable NVRAM 104 may include main I/O data lines MIO (e.g., even main I/O data lines MIOE and odd main I/O data lines MIOO) connected to the local I/O data lines, LIO, via the plurality of (control) switches. Thus, the secondary sense element 303 may be controllable to output from or input to the plurality of sense elements 314 of a subarray 308 of the segment 306 (by the I/O operation) via the local I/O data lines, LIO, and the main I/O data lines, MIO, using the plurality of (control) switches (e.g., output to a global data line, GIO, or input according to data received from the GIO). The segment may be addressed according to the segment address SEGA via a segment enable signal, SEGM_EN.

Adapting the plurality of (control) switches to access a different row buffer according to a different segment address SEGA may also be referred to as reconfiguring the I/O circuit.

In x16 DDR configurations (not having the A pins) and/or as an alternative to using above-described pins of x4 and x8 DDR, the remanent-polarizable NVRAM 104 may include a register and the segment address SEGA may be set via the register. This allows to increase the number of accessible open pages, but reduces the access time due to the slowness of multi-purpose registers.

Optionally, the control circuit may be configured to provide an (new) SELECT command specifying the subarray to be selected.

It is understood, since the memory states of the memory cells of a row can be cached into the row buffer of the corresponding subarray (without any refresh operation), the row buffer can be accessed multiple times and even after the time duration associated with the refresh operation (e.g., 7 μs to 14 μs).

In the example of using the A11, A13, A17, C0, C1, and C2 pins to allow for one open page per segment, it is understood that this page may be closed (by providing the PRE signal) prior to accessing another row (viz. to open another page) of this segment. When having the additional pins which allow to open one page per subarray, the page of the subarray may be closed (by providing the PRE signal) prior to accessing another row (viz. to open another page) of this subarray.

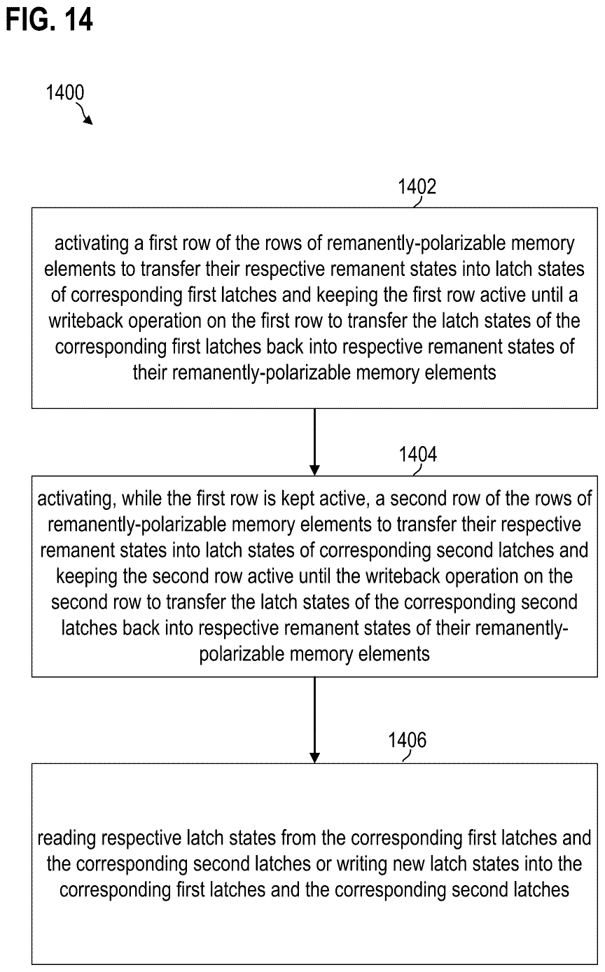

FIG. 14 shows a flow diagram of a method 1400 for quick-reading memory cells of a memory in a double data rate (DDR) configuration according to various aspects. The memory cells may include rows of remanently-polarizable memory elements within a same bank of the memory.

The method 1400 may include (in 1402) activating a first row of the rows of remanently-polarizable memory elements to transfer their respective remanent states into latch states of corresponding first latches and keeping the first row active until a writeback operation on the first row to transfer the latch states of the corresponding first latches back into respective remanent states of their remanently-polarizable memory elements. The first latches may be latches 702 of first sense elements (e.g., of first sense amplifiers).

The method 1400 may include (in 1404) activating, while the first row is kept active, a second row of the rows of remanently-polarizable memory elements to transfer their respective remanent states into latch states of corresponding second latches and keeping the second row active until the writeback operation on the second row to transfer the latch states of the corresponding second latches back into respective remanent states of their remanently-polarizable memory elements. The second latches may be latches 702 of second sense elements (e.g., of second sense amplifiers). The second latches may be different from the first latches.

The method 1400 may include (in 1406) reading respective latch states from the corresponding first latches and the corresponding second latches or writing new latch states into the corresponding first latches and the corresponding second latches.

As detailed herein, since there may be no refresh operation, the latch states of the first latches and/or second latches may be read even after a time duration of 14 μs or more.

It may be intended that aspects described in relation to one or more of the methods may apply also to the memory cell arrangement, and vice versa. For example, a method may include an execution of one or more functions a component of the memory cell arrangement (e.g., the one or more write modification circuits) is configured to.

In the following, various examples are provided that may include one or more aspects described above with reference to the memory device (short: memory) 100 and to the method described herein. It may be intended that aspects described in relation to one or more of the methods may apply also to the memory cell and/or the memory cell arrangement, and vice versa.

Example 1 is a memory including: a memory bank including a first memory row and a second memory row, wherein the first memory row includes a first memory array addressable by a first set of wordlines and a first set of bitlines, the first set of bitlines connected to a corresponding first set of sense elements, wherein the second memory row includes a second memory array addressable by a second set of wordlines and a second set of second bitlines, the second set of bitlines connected to a corresponding second set of sense elements; an input-output (I/O) circuit configurable to, in an I/O operation, selectively input to or output from the first set of sense elements and the second set of sense elements; and a control circuit configured to: perform a read operation on the first memory array to store a first word associated with the first set of wordlines in the corresponding first set of sense elements; perform the read operation on the second memory array to store a second word associated with the second set of wordlines in the corresponding second set of sense elements; and operate the I/O circuit to perform the I/O operation on one or more operated sense elements of the first set of sense elements or of the second set of sense elements as a function of a first address associated with the I/O operation of the first memory row and a second address associated with the I/O operation of the second memory row.

In Example 2, the subject matter of Example 1 can optionally include that the control circuit is configured to operate the I/O circuit to perform the I/O operation on the one or more operated sense elements before the control circuit performs another read operation on the first memory array or the second memory array.

In Example 3, the subject matter of any one of Examples 1 to 2 can optionally include that the control circuit is further configured to operate the I/O circuit to, before the control circuit performs another read operation on the first memory array or the second memory array, perform the I/O operation on at least one first operated sense element of the first set of sense elements and at least one second operated sense element of the second set of sense elements.

In Example 4, the subject matter of any one of Examples 1 to 3 can optionally include that the control circuit is further configured to, after the read operation on the first memory array, perform a writeback operation to write from the corresponding first set of sense elements into the first memory array, wherein the control circuit is further configured to, after the read operation on the second memory array, perform a writeback operation to write from the corresponding second set of sense elements into the second memory array.

In Example 5, the subject matter of Example 4 can optionally include that the control circuit is further configured to operate the I/O circuit to, before the control circuit performs the writeback operation on the second memory array, perform the I/O operation on at least one first operated sense element of the first set of sense elements and at least one second operated sense element of the second set of sense elements.

In Example 6, the subject matter of any one of Examples 4 to 5 can optionally include that the control circuit is further configured to, before the control circuit performs the writeback operation on the first memory array, perform the I/O operation to store a new first word associated with the first set of wordlines or to, before the control circuit performs the writeback operation on the second memory array, perform the I/O operation to store a new second word associated with the second set of wordlines.

In Example 7, the subject matter of any one of Examples 4 to 6 can optionally include that the control circuit is configured to perform, after the control circuit performs the read operation on the first and second memory arrays and before the control circuit performs the writeback operation on the first memory array, one or more I/O operations on the first set of sense elements over a duration of more than 14 microseconds.

In Example 8, the subject matter of any one of Examples 1 to 7 can optionally include that the control circuit is configured to, after at least 14 microseconds from performing the read operation on the first memory array and the second memory array, operate the I/O circuit to perform the I/O operation on the one or more operated sense elements.

In Example 9, the subject matter of any one of Examples 1 to 8 can optionally include that the first set of sense elements includes a first set of latches to store the first word and the second set of sense elements includes a second set of latches to store the second word.

In Example 10, the subject matter of any one of Examples 1 to 9 can optionally include that the first memory array and the second memory array include memory elements that are remanently polarizable to at least two different remanent polarization states.

In Example 11, the subject matter of any one of Examples 1 to 10 can optionally include that the I/O circuit includes a (secondary) sense amplifier.

In Example 12, the subject matter of Example 11 can optionally include that (secondary) sense amplifier of the I/O circuit is shared among the first memory row and the second memory row.

In Example 13, the memory of Example 12 can optionally further include control switches to connect either the first memory row or the second memory row to the (secondary) sense amplifier of the I/O circuit, wherein a configuration of the control switches is based on the first address or the second address.

In Example 14, the subject matter of any one of Examples 1 to 13 can optionally include that the memory is in a double data rate (DDR) memory configuration.

Example 15 is a memory including: a first set of memory cells grouped into a first row; a second set of memory cells grouped into a second row; an activation circuit configured to: sense, when the first row is in an activated state, a first stored state from a corresponding first memory cell of the first set of memory cells into an associated first sense element for the corresponding first memory cell; and sense, when the second row is in the activated state, a second stored state from a corresponding second memory cell of the second set of memory cells into an associated second sense element for the corresponding second memory cell; and a control circuit configured to: place both the first row and the second row into the activated state; and operate an input-output circuit to, after the first row and the second row have been placed into the activated state, obtain the first stored state from the associated first sense element and the second stored state from the associated second sense element.

In Example 16, the subject matter of Example 15 can optionally include that the input-output circuit is configurable to obtain the first stored state from the associated first sense element or the second stored state from the associated second sense element as a function of a row address for the first row or the second row.

In Example 17, the subject matter of any one of Examples 15 to 16 can optionally include that the control circuit is configured to operate the input-output circuit to obtain the first stored state from the associated first sense element and the second stored state from the associated second sense element by having the control circuit being further configured to, while the first row and the second row remain in the activated state: operate the input-output circuit to obtain the first stored state from the associated first sense element; reconfigure the input-output circuit for obtaining the second stored state from the associated second sense element; and operate the input-output circuit to obtain the second stored state from the associated second sense element.

In Example 18, the subject matter of any one of Examples 15 to 17 can optionally include that the activated state is associated with a writeback operation, wherein the writeback operation of the first row ends the first row being in the activated state by writing a first logic value of the associated first sense element into a remanent state of the corresponding first memory cell, wherein the writeback operation of the second row ends the second row being in the activated state by writing a second logic value of the associated second sense element into a remanent state of the corresponding first memory cell.

In Example 19, the subject matter of any one of Examples 15 to 18 can optionally include that the first row and the second row are within a same bank of the memory.

In Example 20, the subject matter of any one of Examples 15 to 19 can optionally include that the input-output circuit includes a (secondary) sense amplifier shared between the first row and the second row.

In Example 21, the subject matter of any one of Examples 15 to 20 can optionally include that the associated first sense element and the associated second sense element each includes a latch.

In Example 22, the subject matter of any one of Examples 15 to 21 can optionally include that the first set of memory elements and the second set of memory elements include remanently-polarizable memory elements that are remanently polarizable to at least two different remanent states.

In Example 23, the subject matter of Example 22 can optionally include that the activation circuit configured to sense in the activated state includes the activation circuit configured to apply a read voltage to the remanently-polarizable memory elements, wherein the read voltage is sufficient to remanently polarize the remanently-polarizable memory elements to one of the at least two different remanent states.

Example 24 is a method for quick-reading memory cells of a memory in a double data rate (DDR) configuration, wherein the memory cells include rows of remanently-polarizable memory elements within a same bank of the memory, the method including: activating a first row of the rows of remanently-polarizable memory elements to transfer their respective remanent states into latch states of corresponding first latches and keeping the first row active until a writeback operation on the first row to transfer the latch states of the corresponding first latches back into respective remanent states of their remanently-polarizable memory elements; activating, while the first row is kept active, a second row of the rows of remanently-polarizable memory elements to transfer their respective remanent states into latch states of corresponding second latches and keeping the second row active until the writeback operation on the second row to transfer the latch states of the corresponding second latches back into respective remanent states of their remanently-polarizable memory elements; and reading respective latch states from the corresponding first latches and the corresponding second latches or writing new latch states into the corresponding first latches and the corresponding second latches.

In Example 25, the subject matter of Example 24 can optionally include that the reading of the respective remanent states from the corresponding first latches is completed before a re-activating of the first row of the rows of remanently-polarizable memory elements to read their respective remanent states into the corresponding first latches.

In Example 26, the subject matter of any one of Examples 24 to 25 can optionally include that the reading of the respective remanent states from the corresponding second latches is completed before a re-activating of the second row of the rows of remanently-polarizable memory elements to read their respective remanent states into the corresponding second latches.

In Example 27, the method of any one of Examples 24 to 26 can optionally further include: waiting for at least 14 microseconds after performing the activating of the first row and the second row before the reading of the respective remanent states.

In Example 28, the subject matter of any one of Examples 24 to 27 can optionally include that the respective remanent states include different remanent-polarizable states of the rows of remanently-polarizable memory elements, wherein the latch states include different logic level corresponding to the different remanent-polarizable states.

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g., provided by a metal or degenerate semiconductor in absence of p-n junctions in the current path. The term “electrically conductively connected” may be also referred to as “galvanically connected”.

The term “coupled to” used herein with reference to functional parts of a memory cell (e.g., functional parts of a memory structure) that are coupled to respective nodes (e.g., plateline node, bitline node, and/or wordline node) of the memory cell may be understood as follows: the respective functional parts are electrically conductively connected to corresponding nodes and/or the respective functional parts itself provide the corresponding nodes. As an example, a source/drain node of a field-effect transistor memory structure may be electrically conductively connected to the source-line node of the memory cell or the source/drain node of the field-effect transistor memory structure may provide the source-line node of the memory cell. As another example, a source/drain node of the field-effect transistor memory structure may be electrically conductively connected to the bitline node of the memory cell or the source/drain node of the field-effect transistor memory structure may provide the bitline node of the memory cell.

The term “voltage” may be used herein with respect to “one or more bitline voltages”, “one or more wordline voltages”, “one or more plateline voltages”, “one or more sourceline voltages”, “one or more control line voltages”, “one or more base voltages” and the like. As an example, the term “base voltage” may be used herein to denote a reference voltage and/or a reference potential for the circuit. With respect to an electrical circuit, the base voltage may be also referred to as ground voltage, ground potential, virtual ground voltage, or zero volts (0 V). The base voltage of an electrical circuit may be defined by the power supply used to operate the electronic circuit. In the figures, the base voltage is exemplarily indicated using the ground symbol (also referred to as earth symbol). As another example, the term “control line voltage” may be used herein to denote a voltage that is provided to a control line, e.g., of a memory cell arrangement (for example a “wordline voltage” may be provided to a “wordline”, a “bitline voltage” may be provided to a bitline, and a “sourceline voltage” may be provided to a sourceline). The sign of a voltage difference (e.g., a voltage drop) may be defined as a potential inside a memory cell (e.g., at a first electrode portion) minus a potential at a second electrode portion of the memory cell.

Illustratively, a voltage provided to a node or a terminal may assume any suitable value depending on the intended operation of the circuit including the node or terminal. For example, a bitline voltage (referred to as V_{BL} or VBL) may be varied depending on the intended operation of the memory cell arrangement. Analogously, a wordline voltage (referred to as V_{WL} or VWL), a plateline voltage (referred to as V_{PL} or VPL), and/or plateline voltage (referred to as V_{PL} or VPL) may be varied depending on the intended operation of a memory cell arrangement. A voltage provided to a node or terminal may be defined by the respective potential applied to that node or terminal relative to the base voltage (referred to as V_{B}) of the circuit. Further, a voltage drop associated with two distinct nodes or terminals of a circuit may be defined by the respective voltages/potentials applied at the two nodes or terminals. As an example, a bitline voltage drop associated with a memory cell of a memory cell arrangement (e.g., an electrode of the memory cell) may be defined by the respective voltages/potentials applied at the corresponding memory cell (e.g., the electrode of the memory cell). A voltage drop over (short: a voltage over) over a component may also be referred to as a “voltage across” the component. Thus, a “voltage across” a component may be used herein to denote a voltage drop from a node on one side of a component (e.g. one side of a capacitor) to a node on the other side of the component (e.g., the other side of the capacitor).

The term “region” used with regards to a “source region”, “drain region”, “channel region”, and the like, may be used herein to mean a continuous region of a semiconductor portion (e.g., of a semiconductor wafer or a part of a semiconductor wafer, a semiconductor layer, a fin, a semiconductor nanosheet, a semiconductor nanowire, etc.,). In some aspects, the continuous region of a semiconductor portion may be provided by semiconductor material having only one dominant doping type.

In some aspects, two voltages may be compared with one another by relative terms such as “greater”, “higher”, “lower”, “less”, or “equal”, for example. It is understood that, in some aspects, a comparison may include the sign (positive or negative) of the voltage value or, in other aspects, the absolute voltage values (also referred to as the magnitude, or as the amplitude, e.g., of a voltage pulse) are considered for the comparison.

The terms “charging” or “discharging” an element having a capacitance associated therewith (such as a control line, a terminal, a capacitor (e.g., a capacitive memory element), etc., in an electronic circuit) may be used herein with respect to increase (in case of charging) or decrease (in case of discharging) the amount of electric charge stored in the element, for example. The electric charge stored in the element (based on the capacitance associated therewith) may be changed via a charging current or discharging current accordingly. In the case that an element having a capacitance associated therewith has an amount of electric charge stored therein, a corresponding voltage may be associated therewith as well. The relationship between a voltage of an element having a capacitance associated therewith (e.g., of a capacitor or an element having an inherent capacitance) and the electric charge stored therein may be determined based on commonly used equations considering the capacitance as a ratio of a change in electric charge to a corresponding change in the electric potential. The terms “charging” or “discharging” with reference to an element having a capacitance associated therewith may be used herein with respect to a technical current direction. The term “charge” or “charging” with reference to an element having a capacitance associated therewith, such as a control line, may be used herein to mean an increase of a voltage value being present (e.g., measurable) at the element, e.g., at the control line. The increase of the voltage value may be understood as a more positive voltage value: For example, an element having a capacitance associated therewith may be charged from a voltage value of -8V to a voltage value of -4V, from a voltage value of - 2V to a voltage value of 2V, or from a voltage value of 3V to a voltage value of 6V (only as numerical examples). The term “discharge” or “discharging” with reference to an element having a capacitance associated therewith, such as a control line, may be used herein to mean a decrease of a voltage value being present (e.g., measurable) at the element, e.g., at the control line. The decrease of the voltage value may mean a more negative voltage value: For example, an element having a capacitance associated therewith may be discharged from a voltage value of 8V to a voltage value of 4V, from a voltage value of 2V to a voltage value of −2V, or from a voltage value of −3V to a voltage value of −6V (only as numerical examples).

The terms “electrically conducting” or “electrically conductive” may be used herein interchangeably to describe a material or a layer having an electrical conductivity or an average electrical conductivity greater than 10⁶ S/m at a temperature of 20° C. The term “electrically insulating” may be used herein interchangeably to describe a material or a layer having an electrical conductivity or an average electrical conductivity less than 10⁻¹⁰ S/m at a temperature of 20° C. In some aspects, a difference in electrical conductivity between an electrically conducting material (or layer) and an electrically insulating material (or layer) may have an absolute value of at least 10¹⁰ S/m at a temperature of 20° C., or of at least 10¹⁵ S/m at a temperature of 20° C.

It may be understood, that the physical term “electrical conductivity” (also referred to as specific conductance, specific electrical conductance, as examples) may be defined as a material dependent property reciprocal to the physical term “electrical resistivity” (also referred to as specific electrical resistance, volume resistivity, as examples). Further properties of a layer or structure may be defined material dependent and the geometry dependent, e.g., by the physical terms “electrical resistance” and “electrical conductance”.

The terms “at least one” and “one or more” may be understood to include any integer number greater than or equal to one, i.e. one, two, three, four, [ . . . ], etc. The term “a plurality” or “a multiplicity” may be understood to include any integer number greater than or equal to two, i.e. two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The phrase that an element or a group of elements “includes” another element or another group of elements may be used herein to mean that the other element or other group of elements may be part of the element or the group of elements or that the element or the group of elements may be configured or formed as the other element or the other group of elements (e.g., the element may be the other element).

The phrase “unambiguously assigned” may be used herein to mean a one-to-one-assignment (e.g., allocation, e.g., correspondence) or a bijective assignment. As an example, a first element being unambiguously assigned to a second element may include that the second element is unambiguously assigned to the first element. As another example, a first group of elements being unambiguously assigned to a second group of element may include that each element of the first group of elements is unambiguously assigned to a corresponding element of the second group of elements and that that corresponding element of the second group of elements is unambiguously assigned to the element of the first group of elements.

A memory may either be volatile or non-volatile. Both, a volatile memory and a non-volatile memory may be configured to store data thereon. A volatile memory may require constant power in order to store data. Thus, once the power is lost, the stored data are gone. Hence, a volatile memory may store data non-persistently. A non-volatile memory, on the other hand, may also store the data once the power is removed. Hence, a non-volatile memory may store data persistently.

The word “over”, used herein to describe forming a feature, e.g. a layer “over” a side or surface, may be used to mean that the feature, e.g. the layer, may be formed “directly on”, e.g. in direct contact with, the implied side or surface. The word “over”, used herein to describe forming a feature, e.g. a layer “over” a side or surface, may be used to mean that the feature, e.g. the layer, may be formed “indirectly on” the implied side or surface with one or more additional layers being arranged between the implied side or surface and the formed layer.

It is noted that one or more functions described herein with reference to a memory cell, a memory cell arrangement, etc., may be accordingly part of a method, e.g., part of a method for operating a memory cell arrangement. Vice versa, one or more functions described herein with reference to a method, e.g., with reference to a method for operating a memory cell arrangement, may be implemented accordingly in a device or in a part of a device, for example, in a memory cell, a memory cell arrangement, etc.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

11. A memory comprising:
a memory bank comprising a first memory row and a second memory row,
wherein the first memory row comprises a first memory array addressable by a first set of wordlines and a first set of bitlines, the first set of bitlines connected to a corresponding first set of sense elements,
wherein the second memory row comprises a second memory array addressable by a second set of wordlines and a second set of second bitlines, the second set of second bitlines connected to a corresponding second set of sense elements;
an input-output (I/O) circuit configurable to, in an I/O operation, selectively input to or output from the first set of sense elements and the second set of sense elements; and
a control circuit configured to:
perform a read operation on the first memory array to store a first word associated with the first set of wordlines in the corresponding first set of sense elements;
perform the read operation on the second memory array to store a second word associated with the second set of wordlines in the corresponding second set of sense elements; and
operate the I/O circuit to perform the I/O operation on one or more operated sense elements of the first set of sense elements or of the second set of sense elements as a function of a first address associated with the I/O operation of the first memory row and a second address associated with the I/O operation of the second memory row.

122. The memory according to claim 1, wherein the control circuit is further configured to operate the I/O circuit to perform the I/O operation on the one or more operated sense elements before the control circuit performs another read operation on the first memory array or the second memory array.

3. The memory according to claim 1, wherein the control circuit is further configured to operate the I/O circuit to, before the control circuit performs another read operation on the first memory array or the second memory array, perform the I/O operation on at least one first operated sense element of the first set of sense elements and at least one second operated sense element of the second set of sense elements.

4. The memory according to claim 1, wherein the control circuit is further configured to:
after the read operation on the first memory array, perform a writeback operation to write from the corresponding first set of sense elements into the first memory array,
after the read operation on the second memory array, perform a writeback operation to write from the corresponding second set of sense elements into the second memory array;
before the control circuit performs the writeback operation on the first memory array, perform the I/O operation to store a new first word associated with the first set of wordlines or to, before the control circuit performs the writeback operation on the second memory array, perform the I/O operation to store a new second word associated with the second set of wordlines.

5. The memory according to claim 1, wherein the control circuit is further configured to, after at least 14 microseconds from performing the read operation on the first memory array and the second memory array, operate the I/O circuit to perform the I/O operation on the one or more operated sense elements.

6. The memory according to claim 1, wherein the first set of sense elements comprises a first set of latches to store the first word, and wherein the second set of sense elements comprises a second set of latches to store the second word.

7. The memory according to claim 1, wherein the first memory array and the second memory array comprise memory elements that are remanently polarizable to at least two different remanent polarization states.

8. The memory according to claim 1, wherein the I/O circuit comprises a sense amplifier.

9. The memory according to claim 8, wherein the sense amplifier of the I/O circuit is shared among the first memory row and the second memory row.

10. The memory according to claim 9, further comprising control switches to connect either the first memory row or the second memory row to the sense amplifier of the I/O circuit, wherein a configuration of the control switches is based on the first address or the second address.

11. The memory according to claim 1, wherein the memory is in a double data rate memory configuration.

12. A memory, comprising:
a first set of memory cells grouped into a first row;
a second set of memory cells grouped into a second row;
an activation circuit configured to:
sense, when the first row is in an activated state, a first stored state from a corresponding first memory cell of the first set of memory cells into an associated first sense element for the corresponding first memory cell; and
sense, when the second row is in the activated state, a second stored state from a corresponding second memory cell of the second set of memory cells into an associated second sense element for the corresponding second memory cell; and
a control circuit configured to:
place both the first row and the second row into the activated state; and
operate an input-output circuit to, after the first row and the second row have been placed into the activated state, obtain the first stored state from the associated first sense element and the second stored state from the associated second sense element.

13. The memory according to claim 12, wherein the input-output circuit is further configured to obtain the first stored state from the associated first sense element or the second stored state from the associated second sense element as a function of a row address for the first row or the second row.

14. The memory according to claim 12, wherein the control circuit is configured to operate the input-output circuit to obtain the first stored state from the associated first sense element and the second stored state from the associated second sense element by having the control circuit being further configured to, while the first row and the second row remain in the activated state:
operate the input-output circuit to obtain the first stored state from the associated first sense element;
reconfigure the input-output circuit for obtaining the second stored state from the associated second sense element; and
operate the input-output circuit to obtain the second stored state from the associated second sense element.

15. The memory according to claim 12,
wherein the activated state is associated with a writeback operation,
wherein the writeback operation of the first row ends the first row being in the activated state by writing a first logic value of the associated first sense element into a remanent state of the corresponding first memory cell,
wherein the writeback operation of the second row ends the second row being in the activated state by writing a second logic value of the associated second sense element into a remanent state of the corresponding first memory cell.

16. The memory according to claim 12, wherein the first row and the second row are within a same bank of the memory.

17. The memory according to claim 12, wherein the input-output circuit comprises a sense amplifier shared between the first row and the second row.

18. The memory according to claim 12, wherein the associated first sense element and the associated second sense element each comprises a latch.

19. The memory according to claim 12, wherein the first set of memory elements and the second set of memory elements comprise remanently-polarizable memory elements that are remanently polarizable to at least two different remanent states.

20. A method for quick-reading memory cells of a memory in a double data rate configuration, wherein the memory cells comprise rows of remanently-polarizable memory elements within a same bank of the memory, the method comprising:
activating a first row of the rows of remanently-polarizable memory elements to transfer their respective remanent states into latch states of corresponding first latches and keeping the first row active until a writeback operation on the first row to transfer the latch states of the corresponding first latches back into respective remanent states of their remanently-polarizable memory elements;
activating, while the first row is kept active, a second row of the rows of remanently-polarizable memory elements to transfer their respective remanent states into latch states of corresponding second latches and keeping the second row active until the writeback operation on the second row to transfer the latch states of the corresponding second latches back into respective remanent states of their remanently-polarizable memory elements; and
reading respective latch states from the corresponding first latches and the corresponding second latches or writing new latch states into the corresponding first latches and the corresponding second latches.
